(19) United States
(12) Patent Application Publication
(10) Pub. No.: US 2022/0076925 A1
(43) Pub. Date: Mar. 10, 2022

(54) APPARATUS AND METHOD FOR PROCESSING SUBSTRATE USING PLASMA

(71) Applicant: SEMES Co., Ltd., Chungcheongnam-do (KR)

(72) Inventors: Joun Yaek Koo, Seoul (KR); Seong Gil Lee, Gyeonggi-do (KR); Dong Sub Oh, Busan (KR); Ji Hwan Lee, (KR); Young Je Um, Busan (KR); Dong Hun Kim, Seoul (KR); Wan Jae Park, Gyeonggi-do (KR); Myoung Sub Noh, Gyeonggi-do (KR); Du Ri Kim, Incheon (KR)

(21) Appl. No.: 17/392,586

(22) Filed: Aug. 3, 2021

(30) Foreign Application Priority Data
Sep. 8, 2020 (KR) 10-2020-0114759

(51) Int. Cl. H01J 37/32; H01L 21/02; B08B 7/00; H01L 21/311

(52) U.S. Cl. CPC H01J 37/32449; H01J 37/32422; H01J 37/32568; H01J 2237/3343; H01L 21/02057; B08B 7/0035; H01L 21/31116; H01J 37/32091

(57) ABSTRACT

A substrate processing apparatus and a substrate processing method using plasma capable of controlling an etch rate and/or uniformity according to a position of a substrate are provided. The substrate processing apparatus includes a first space disposed between an electrode and an ion blocker; a second space disposed between the ion blocker and a shower head; a processing space for processing a substrate under the shower head; a first gas supply module for providing a first gas for generating plasma in the first space; a second gas supply module for providing a second gas to be mixed with the effluent of the plasma in the processing space; and a third gas supply module for providing a third gas to be mixed with the effluent of the plasma in the processing space.

### CROSS REFERENCE TO RELATED APPLICATION

This application claims the benefit of Korean Patent Application No. 10-2020-0114759, filed on Sep. 8, 2020, in the Korean Intellectual Property Office, the disclosure of which is incorporated herein by reference in its entirety.

### FIELD OF THE INVENTION

The present invention relates to a substrate processing apparatus and method using plasma.

### DESCRIPTION OF THE RELATED ART

When manufacturing a semiconductor device or a display device, a substrate processing process using plasma may be used. The substrate processing process using plasma includes a capacitively coupled plasma (CCP) method, an inductively coupled plasma (ICP) method, and a combination of the two according to a method of generating plasma. In addition, dry cleaning or dry etching may be performed using plasma.

### SUMMARY OF THE INVENTION

Dry cleaning is an isotropic etching, in which there is less pattern collapse and less damage caused by plasma. However, as the substrate becomes larger and the pattern becomes complex, the etch rate and/or uniformity may not be constant according to the position of the substrate.

The problem to be solved by the present invention is to provide a substrate processing apparatus and a substrate processing method using plasma capable of controlling the etch rate and/or uniformity according to the position of the substrate.

The subject of the present invention is not limited to the problems mentioned above, and other problems that are not mentioned will be clearly understood by those skilled in the art from the following description.

One aspect of the substrate processing apparatus of the present invention for achieving the above object comprises a first space disposed between an electrode and an ion blocker; a second space disposed between the ion blocker and a shower head; a processing space for processing a substrate under the shower head; a first gas supply module for providing a first gas for generating plasma in the first space; a second gas supply module for providing a second gas to be mixed with an effluent of the plasma in the processing space; and a third gas supply module for providing a third gas to be mixed with an effluent of the plasma in the processing space, wherein the first gas is a fluorine-containing gas, the second gas is a nitrogen and hydrogen-containing gas, the third gas is a nitrogen-containing gas different from the second gas, and the substrate includes an exposed silicon and hydrogen-containing region.

Wherein a flow rate control of the second gas and a flow rate control of the third gas may be performed independently. In addition, a uniformity when the third gas is provided at a first flow rate may be higher than a uniformity when the third gas is provided at a second flow rate smaller than the first flow rate.

Wherein the ion blocker may include a first filter region and a second filter region disposed outside the first filter region, and the shower head may include a first shower region and a second shower region disposed outside the first shower region.

Wherein the second gas and the third gas are supplied through the first filter region of the ion blocker, and are not supplied through the second filter region, wherein the second gas and the third gas are not suppled through the first shower region of the shower head, and are supplied through the second shower region.

Wherein the second gas and the third gas are supplied through the first shower region and the second shower region of the shower head, wherein a flow rate of the third gas supplied through the first shower region may be different from a flow rate of the third gas supplied through the second shower region.

Wherein the second gas and the third gas are supplied through the first filter region and the second filter region of the ion blocker, wherein a flow rate of the third gas supplied through the first filter region may be different from a flow rate of the third gas supplied through the second filter region.

Wherein the first gas and the fourth gas are provided through the electrode, and the fourth gas is a hydrogen-containing gas, wherein a flow rate control of the first gas and a flow rate control of the fourth gas may be performed independently.

Wherein the electrode includes a first electrode region and a second electrode region disposed outside the first electrode region, wherein the first gas and the fourth gas are supplied through the first electrode region and the second electrode region, and a flow rate of the fourth gas supplied through the first electrode region and a flow rate of the fourth gas supplied through the second electrode region may be different from each other.

Wherein a flow rate of the fourth gas supplied through the first electrode region is greater than a flow rate of the fourth gas supplied through the second electrode region, wherein a support module for supporting the substrate is disposed in the processing space, and the support module is divided into a plurality of regions, and a temperature of a centrally located region among the plurality of regions may be increased higher than a temperature of other regions.

Wherein an inert gas may be additionally provided through the electrode.

Another aspect of the substrate processing apparatus of the present invention for achieving the above object comprises a first space disposed between an electrode connected to a high frequency power supply and an ion blocker connected to a constant voltage; a second space disposed between the ion blocker and a shower head; a processing space for processing a substrate under the shower head; a first gas supply module for providing nitrogen trifluoride gas for generating plasma through the electrode in the first space; a second gas supply module for providing hydrogen gas for generating plasma through the electrode in the first space; and a third gas supply module for providing a first ammonia gas through a central region of the ion blocker, and providing a second ammonia gas through an edge region of the shower head to mix the first ammonia gas, the second ammonia gas, and an effluent of the plasma.

Wherein a flow rate of the first ammonia gas and a flow rate of the second ammonia gas may be different from each other.

A fourth gas supply module for providing a first nitrogen gas through a central region of the ion blocker to mix the first nitrogen gas and an effluent of the plasma, and providing a second nitrogen gas through an edge region of the shower head to mix the second nitrogen gas and an effluent of the plasma may be further comprised.

Wherein a flow rate of the first nitrogen gas and a flow rate of the second nitrogen gas may be different from each other.

Wherein the electrode includes a first electrode region located at a center and a second electrode region disposed outside the first electrode region, wherein the nitrogen trifluoride gas and the hydrogen gas are supplied through a first electrode region and a second electrode region, a flow rate of the hydrogen gas supplied through the first electrode region and a flow rate of the hydrogen gas supplied through the second electrode region may be different from each other.

Wherein a flow rate of the nitrogen trifluoride gas supplied through the first electrode region and a flow rate of the nitrogen trifluoride gas supplied through the second electrode region may be different from each other.

One aspect of the substrate processing method of the present invention for achieving the above object comprises providing a substrate processing apparatus including a first space disposed between an electrode and an ion blocker, a second space disposed between the ion blocker and a shower head, and a processing space for processing a substrate under the shower head, locating a substrate including an exposed silicon and hydrogen-containing region in the processing space, providing, in a first section, a nitrogen-containing gas and a nitrogen and hydrogen-containing gas in the processing space to form an atmosphere in a chamber, and providing, in a second section, a fluorine-containing gas and a hydrogen-containing gas in the first space while providing a nitrogen-containing gas and a nitrogen and hydrogen-containing gas in the processing space to form a plasma in the first space, and mixing a radical filtered by the ion blocker in an effluent of the plasma, the nitrogen-containing gas, and the nitrogen and hydrogen-containing gas.

An etching uniformity of the substrate is controlled by controlling a flow rate of the nitrogen-containing gas.

Wherein the ion blocker includes a first filter region and a second filter region disposed outside the first filter region, wherein the shower head includes a first shower region and a second shower region disposed outside the first shower region, wherein the nitrogen-containing gas and the nitrogen and hydrogen-containing gas are supplied through the first filter region of the ion blocker, and are not supplied through the second filter region, wherein the nitrogen-containing gas and the nitrogen and hydrogen-containing gas are not supplied through the first shower region of the shower head, and are supplied through the second shower region.

Details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a conceptual diagram illustrating a substrate processing apparatus according to a first embodiment of the present invention;

FIGS. 2a and 2b are views for describing the shower head of FIG. 1;

FIG. 3 is a diagram for describing gas supply in the substrate processing apparatus of FIG. 1;

FIG. 4 is a conceptual diagram illustrating a dry cleaning process of the substrate processing apparatus of FIG. 1;

FIG. 5 is a view for describing a substrate processing apparatus according to a second embodiment of the present invention;

FIG. 6 is a view for describing a substrate processing apparatus according to a third embodiment of the present invention;

FIG. 7 is a view for describing a substrate processing apparatus according to a fourth embodiment of the present invention;

FIG. 8 is a view for describing a substrate processing apparatus according to a fifth embodiment of the present invention;

FIG. 9 is a view for describing a substrate processing apparatus according to a sixth embodiment of the present invention;

FIG. 10 is a view for describing the electrode of FIG. 9; and

FIG. 11 is a conceptual diagram illustrating a support module of the substrate processing apparatus of FIG. 9.

### DETAILED DESCRIPTION OF THE INVENTION

Hereinafter, preferred embodiments of the present invention will be described in detail with reference to the accompanying drawings. Advantages and features of the present invention, and methods for achieving them will be clarified with reference to embodiments described below in detail together with the accompanying drawings. However, the present invention is not limited to the embodiments disclosed below, but may be implemented in various different forms, and only the embodiments allow the publication of the present invention to be complete, and are provided to fully inform those skilled in the technical field to which the present invention pertains of the scope of the invention, and the invention is only defined by the scope of the claims. The same reference numerals refer to the same elements throughout the specification.

When elements are referred to as “on” or “above” of other elements, it includes not only when directly above of the other elements, but also other elements intervened in the middle. On the other hand, when elements are referred to as “directly on” or “directly above,” it indicates that no other element is intervened therebetween.

The spatially relative terms “below,” “beneath,” “lower,” “above,” “upper,” etc., as shown in figures, can be used to easily describe the correlation of components or elements with other components or elements. The spatially relative terms should be understood as terms including the different direction of the element in use or operation in addition to the direction shown in the figure. For example, if the element shown in the figure is turned over, an element described as “below” or “beneath” the other element may be placed “above” the other element. Accordingly, the exemplary term “below” can include both the directions of below and above. The element can also be oriented in other directions, so that spatially relative terms can be interpreted according to the orientation.

Although the first, second, etc. are used to describe various components, elements and/or sections, these components, elements and/or sections are not limited by these terms. These terms are only used to distinguish one component, element, or section from another component, element or section. Therefore, first component, the first element or first section mentioned below may be a second component, second element, or second section within the technical spirit of the present invention.

The terminology used herein is for describing the embodiments and is not intended to limit the present invention. In the present specification, the singular form also includes the plural form unless otherwise specified in the phrase. As used herein, “comprises” and/or “comprising” means that the elements, steps, operations and/or components mentioned above do not exclude the presence or additions of one or more other elements, steps, operations and/or components.

Unless otherwise defined, all terms (including technical and scientific terms) used in the present description may be used with meanings that can be commonly understood by those of ordinary skill in the art to which the present invention belongs. In addition, terms defined in a commonly used dictionary are not interpreted ideally or excessively unless explicitly defined specifically.

Hereinafter, exemplary embodiments of the present invention will be described in detail with reference to the accompanying drawings, and in the description with reference to the accompanying drawings, the same or corresponding elements are assigned the same reference numbers regardless of reference numerals, and the description overlapped therewith will be omitted.

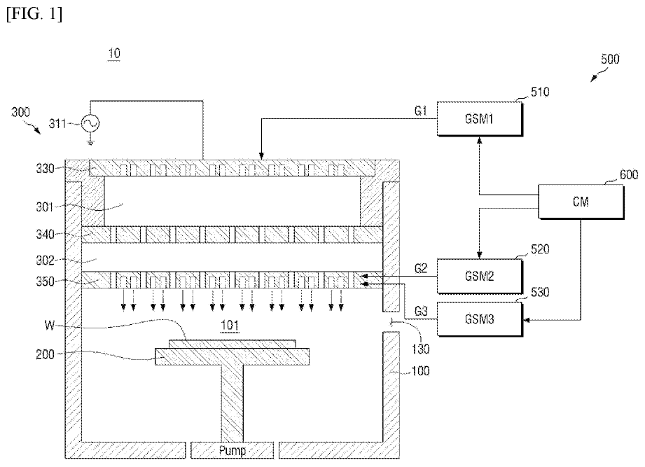

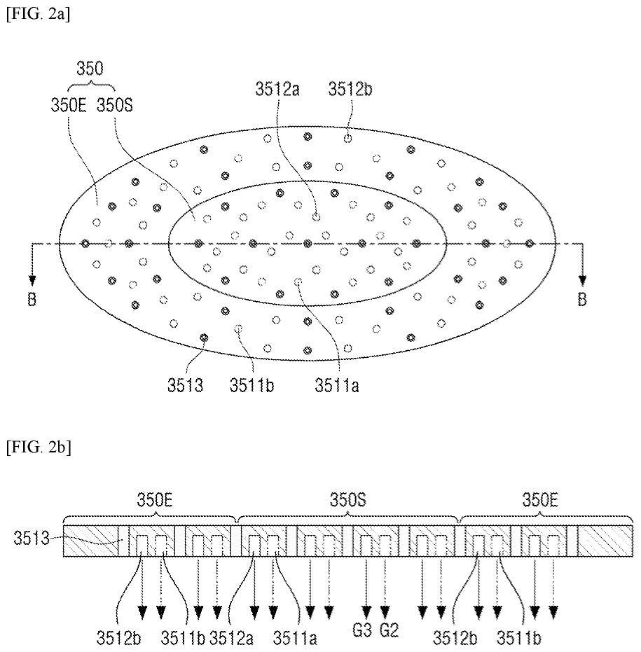

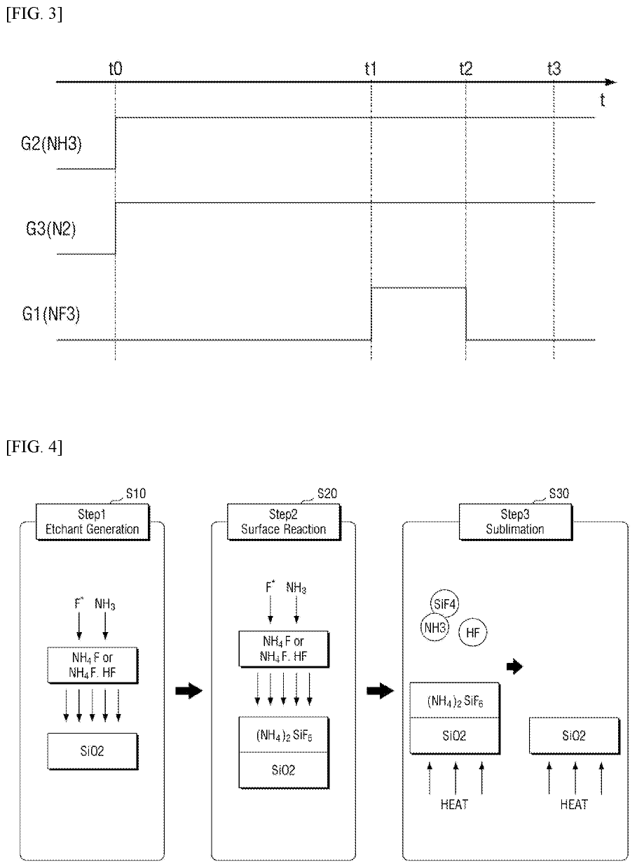

FIG. 1 is a conceptual diagram illustrating a substrate processing apparatus according to a first embodiment of the present invention. FIGS. 2a and 2b are views for describing the shower head of FIG. 1. FIG. 2b is a cross-sectional view taken along line B-B of FIG. 2a. FIG. 3 is a diagram for describing gas supply in the substrate processing apparatus of FIG. 1. FIG. 4 is a conceptual diagram illustrating a dry cleaning process of the substrate processing apparatus of FIG. 1.

First, referring to FIG. 1, the substrate processing apparatus 10 according to the first embodiment of the present invention comprises a process chamber 100, a support module 200, an electrode module 300, a gas supply module 500, a control module 600, etc.

The process chamber 100 provides a processing space 101, in which the substrate (W) is processed therein. The process chamber 100 may have a circular cylindrical shape. The process chamber 100 is made of a metal material. For example, the process chamber 100 may be made of aluminum material. An opening 130 is formed in one side wall of the process chamber 100. The opening 130 is used as an entrance through which the substrate (W) can be carried in or out. The entrance can be opened and closed by a door. An exhaust port (not shown) is installed on the bottom surface of the process chamber 100. The exhaust port functions as an outlet 150, through which by-products generated in the processing space 101 are discharged to the outside of the process chamber 100. The exhaust operation is performed by the pump.

The support module 200 is installed in the processing space 102 and supports the substrate (W). The support module 200 may be an electrostatic chuck that supports the substrate (W) using electrostatic force, but is not limited thereto. The electrostatic chuck may comprise a dielectric plate, in which the substrate (W) is placed on an upper surface, an electrode that is installed in the dielectric plate and provides electrostatic force so that the substrate (W) is adsorbed to the dielectric plate, and a heater installed in the dielectric plate for heating the substrate (W) to control temperature of the substrate (W).

The electrode module 300 includes an electrode (or upper electrode) 330, an ion blocker 340, a shower head 350, and the like, and serves as a capacitively coupled plasma source. The gas supply module 500 includes a first gas supply module 510, a second gas supply module 520, and a third gas supply module 530. The control module 600 controls gas supply of the gas supply modules 510, 520, and 530. The gas supply method by the gas supply module 500 and the control module 600 will be described in detail later with reference to FIGS. 2, 3, 5 to 8, and 10.

A first space 301 is disposed between the electrode 330 and the ion blocker 340, and a second space 302 is disposed between the ion blocker 340 and the shower head 350. A processing space 101 is located under the shower head 350.

The electrode 330 may be connected to a high frequency power supply 311, and the ion blocker 340 may be connected to a constant voltage (e.g., a ground voltage). The electrode 330 includes a plurality of first supply holes. The first gas supply module 510 provides the first gas (G1) to the first space 301 through the electrode 330 (i.e., the first supply hole of the electrode 330). The electromagnetic field generated between the electrode 330 and the ion blocker 340 excites the first gas (G1) in a plasma state. The first gas excited in a plasma state (i.e., plasma effluent) comprises radicals, ions and/or electrons.

The ion blocker 340 is formed of a conductive material, and may have, for example, a plate shape such as a disk. The ion blocker 340 may be connected with a constant voltage. The ion blocker 340 includes a plurality of first through holes formed in the vertical direction. In the plasma effluent, radicals or uncharged neutral species may pass through the first through hole of the ion blocker 340. On the other hand, charged species (i.e., ions) are difficult to pass through the first through hole of the ion blocker 340.

The shower head 350 is formed of a conductive material, and may have a plate shape such as a disc. The shower head 350 may be connected with a constant voltage. The shower head 350 includes a plurality of second through holes formed in the vertical direction. The plasma effluent passing through the ion blocker 340 is provided to the processing space 101 through the second space 302 and the second through hole of the shower head 350.

Here, referring to FIGS. 1 and 2a and 2b, the shower head 350 includes a plurality of second supply holes 3511a and 3511b and a plurality of third supply holes 3512a and 3512b. The second gas supply module 520 provides the second gas (G2) to the processing space 101 through the shower head 350 (that is, the second supply holes 3511a and 3511b of the shower head 350). The third gas supply module 530 provides the third gas (G3) to the processing space 101 through the shower head 350 (that is, the third supply holes 3512a and 3512b of the shower head 350). In the processing space 101, the second gas (G2) and the third gas (G3) are mixed with the plasma effluent passing through the ion blocker 340.

Meanwhile, a patterned structure is formed on the substrate (W), and in particular, the exposed silicon and hydrogen-containing region may be included. The silicon and hydrogen-containing region may be, for example, silicon oxide (SiO2).

In order to dry-clean the exposed silicon and hydrogen-containing region, a fluorine-containing gas may be used as the first gas (G1), a nitrogen and hydrogen-containing gas may be used as the second gas (G2), and a nitrogen-containing gas may be used as the third gas (G3). The third gas (G3) is different from the second gas (G2). For example, the first gas (G1) may be nitrogen trifluoride (NF₃) gas, the second gas G2 may be ammonia (NH₃) gas, and the third gas (G3) may be nitrogen (N₂) gas.

Nitrogen trifluoride (NF₃) is excited in the form of plasma, and the plasma effluent reacts with ammonia (NH₃) to form an etchant for etching silicon oxide.

Nitrogen gas (N₂) plays a role of adjusting the uniformity of etching. When the flow rate of the nitrogen gas is increased, the etch rate decreases and the uniformity increases. Conversely, when the flow rate of the nitrogen gas is decreased, the etch rate increases and the uniformity decreases. By controlling the flow rate of the nitrogen gas independently from the flow rate of the ammonia gas, the uniformity can be precisely controlled.

Here, a process of dry cleaning the exposed silicon oxide will be described in more detail with reference to FIGS. 3 and 4.

First of all, referring to FIG. 3, before forming plasma at time t0, the second gas (G2) (ammonia gas) and the third gas G3 (nitrogen gas) are provided in the processing space 101 of the process chamber 100 to form a process atmosphere.

Between time t1 and time t2, a first gas G1 (nitrogen trifluoride gas) is provided to the first space 301. In addition, a high frequency power supply 311 is supplied to the electrode 330 to excite the first gas (G1) in the form of plasma in the first space 301. Plasma effluents such as radicals, ions and/or electrons are formed. The ions are filtered by the ion blocker 340 and the remaining plasma effluent may pass through the ion blocker 340. The plasma effluent passing through the ion blocker 340 is provided to the processing space 101 through the second space 302 and the shower head 350. The plasma effluent passing through the ion blocker 340 and the second gas (G2) (ammonia gas) react and mix with each other to form an etchant in the processing space 101.

Here, referring to FIG. 4, a fluorine-containing radical (F*, NF₃*, etc.), which is a plasma effluent, reacts with ammonia gas (NH₃) to form an etchant (NH₄F* or NH₄F*.HF*) that can easily react with silicon oxide (SiO₂) (510).

NH₃+NF₃*→NH₄F* or NH₄F*.HF* (Chemical Formula 1)

Subsequently, the etchant (NH₄F* or NH₄F*.HF*) reacts with the surface of the silicon oxide (S20). As a result of the reaction, products such as (NH₄)₂SiF₆ and H₂O can be formed. Here, H₂O is vapor, and (NH₄)₂SiF₆ remains thin on the silicon oxide surface as a solid. In(NH₄)₂SiF₆, silicon (Si) comes from exposed silicon oxide, and nitrogen, hydrogen, fluorine, etc. forming the remainder come from plasma effluent, second gas (G2) (ammonia gas) and/or third gas (G3) (nitrogen gas). During this reaction process, the temperature of the processing space 101 may be maintained at 20° C. to 100° C.

NH₄F* or NH₄F*.HF*+SiO₂→(NH₄)₂SiF₆(s)+H₂O (Chemical Formula 2)

Referring again to FIG. 3, at time t3, the pump is operated to remove by-products. Specifically, as shown in S30 of FIG. 4, since H₂O or the like is vapor, it can be removed by a pump. The temperature of the processing space 101 is increased to 100° C. or higher to sublimate (NH₄)₂SiF₆. The sublimated (NH₄)₂SiF₆ can also be removed by pump operation.

Meanwhile, as described above, the third gas supply module (530 in FIG. 1) provides the third gas (G3) (nitrogen gas) to the processing space (101 in FIG. 1).

When the third gas (G3) (nitrogen gas) is provided in the processing space 101, the etch rate of silicon oxide can be decreased and uniformity can be increased. This is because the amount of NH₄F* increases while HF* decreases in etchant.

N₂⬆+NH₄F*.HF*→NH₄F* ⬆+HF*⬇ (Chemical Formula 3)

In this way, by controlling the flow rate of the third gas (G3) supplied to the processing space 101, the uniformity of the substrate can be controlled. In particular, the third gas supply module (530 in FIG. 1) operates separately (that is, independently) from the second gas supply module (520 in FIG. 1) to independently control the flow rate of the third gas (G3).

In addition, as shown in FIGS. 2a and 2b, the shower head 350 includes a first shower region 350S and a second shower region 350E disposed outside the first shower region 350S. The first shower region 350S may be disposed in a central region of the shower head 350, and the second shower region 350E may be disposed in an edge region of the shower head 350.

The second gas (G2) and the third gas (G3) may be supplied through the first shower region 350S and the second shower region 350E. The second gas G2 is supplied through the second supply hole 3511a of the first shower region 350S and through the second supply hole 3511b of the second shower region 350E. The third gas (G3) is supplied through the third supply hole 3512a of the first shower region 350S and through the third supply hole 3512b of the second shower region 350E.

The flow rate of the third gas (G3) supplied through the first shower region 350S and the flow rate of the third gas (G3) supplied through the second shower region 350E may be controlled differently.

When the flow rate of the third gas (G3) supplied through the first shower region 350S is greater than the flow rate of the third gas (G3) supplied through the second shower region 350E, the third gas (G3) increases on the central region of the substrate (W) corresponding to the first shower region 350S. Accordingly, the etch rate in the central region of the substrate (W) decreases and the uniformity increases.

On the other hand, when the flow rate of the third gas (G3) supplied through the second shower region 350E is greater than the flow rate of the third gas (G3) supplied through the first shower region 350S, the third gas (G3) increases on the edge region of the substrate (W) corresponding to the second shower region 350E. Accordingly, the etch rate in the edge region of the substrate (W) decreases and the uniformity increases.

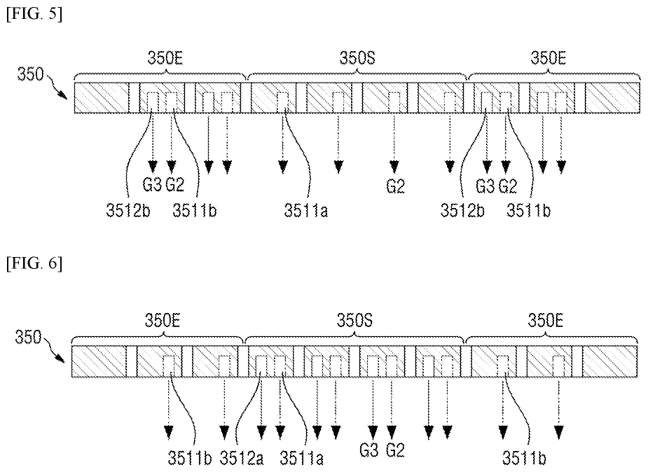

FIG. 5 is a view for describing a substrate processing apparatus according to a second embodiment of the present invention. FIG. 6 is a view for describing a substrate processing apparatus according to a third embodiment of the present invention. Hereinafter, differences from those described with reference to FIGS. 1 to 4 will be mainly described.

First of all, referring to FIG. 5, the second gas (G2) is supplied through the second supply hole 3511a of the first shower region 350S and through the second supply hole 3511b of the second shower region 350E. The third gas (G3) is supplied only through the third supply hole 3512b of the second shower region 350E, and is not supplied through the first shower region 350S. Accordingly, the third gas G3 is relatively small on the central region of the substrate (W), and the third gas (G3) is increased on the edge region of the substrate (W). Accordingly, the etch rate in the edge region of the substrate (W) decreases and the uniformity increases.

Referring to FIG. 6, the second gas (G2) is supplied through the second supply hole 3511a of the first shower region 350S and through the second supply hole 3511b of the second shower region 350E. The third gas (G3) is supplied only through the third supply hole 3512a of the first shower region 350S, and is not supplied through the second shower region 350E. Accordingly, the third gas (G3) is relatively small on the edge region of the substrate (W), and the third gas (G3) is increased on the central region of the substrate (W). Accordingly, the etch rate in the central region of the substrate (W) decreases and the uniformity increases.

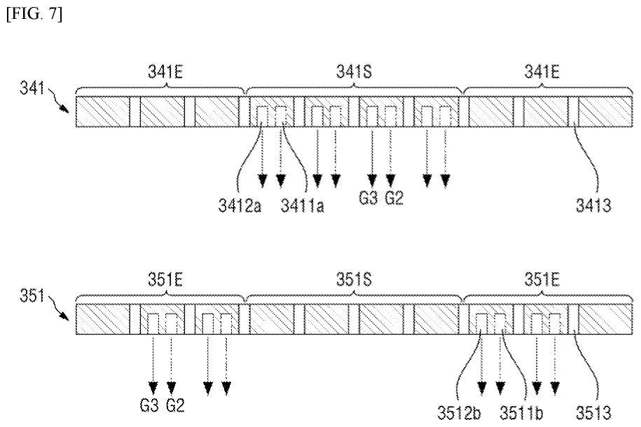

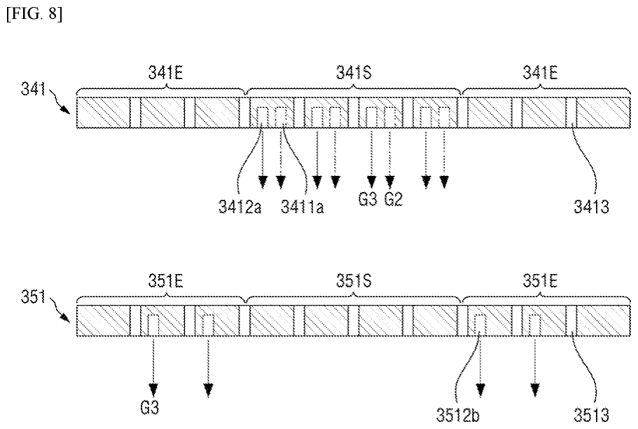

FIG. 7 is a view for describing a substrate processing apparatus according to a fourth embodiment of the present invention. FIG. 8 is a view for describing a substrate processing apparatus according to a fifth embodiment of the present invention. Hereinafter, differences from those described with reference to FIGS. 1 to 6 will be mainly described.

First, referring to FIG. 7, the ion blocker 341 includes a first filter region 341S and a second filter region 341E disposed outside the first filter region 341S. The first filter region 341S may be disposed in a central region of the ion blocker 341, and the second filter region 341E may be disposed in an edge region of the ion blocker 341.

The shower head 351 includes a first shower region 351S and a second shower region 351E disposed outside the first shower region 351S. The first shower region 351S may be disposed in a central region of the shower head 351, and the second shower region 351E may be disposed in an edge region of the shower head 351.

In particular, the supply holes 3411a and 3412a may be formed in the first filter region 341S of the ion blocker 341, and the supply hole may not be formed in the second filter region 341E. On the other hand, the supply hole is not formed in the first shower region 351S of the shower head 351, and the supply holes 3511b and 3512b are formed in the second shower region 351E. A through hole 3513 is formed in the front of the shower head 351.

In this structure, the second gas (G2) and the third gas (G3) may be supplied through the first filter region 341S and the second shower region 351E. The second gas (G2) is supplied through the supply hole 3411a of the first filter region 341S and through the supply hole 3511b of the second shower region 351E. The third gas (G3) is supplied through the supply hole 3412a of the first filter region 341S and through the third supply hole 3512b of the second shower region 351E. The second gas (G2) and the third gas (G3) supplied through the first filter region 341S are provided to the processing space 101 through the through hole 3513.

Meanwhile, the flow rate of the third gas (G3) supplied through the first filter region 341S and the flow rate of the third gas (G3) supplied through the second shower region 351E may be controlled differently.

When the flow rate of the third gas (G3) supplied through the first filter region 341S is greater than the flow rate of the third gas (G3) supplied through the second shower region 351E, the third gas (G3) increases on the central region of the substrate (W) corresponding to the first filter region 341S. Accordingly, the etch rate in the central region of the substrate (W) decreases and the uniformity increases.

On the other hand, when the flow rate of the third gas (G3) supplied through the second shower region 351E is greater than the flow rate of the third gas (G3) supplied through the first filter region 341S, the third gas (G3) increases on the edge region of the substrate (W) corresponding to the second shower region 351E. Accordingly, the etch rate in the edge region of the substrate (W) decreases and the uniformity increases.

Referring to FIG. 8, in the same structure as in FIG. 7, the second gas (G2) is supplied only through the first filter region 341S, and the third gas (G3) may be supplied through the first filter region 341S and the second shower region 351E.

The second gas (G2) is supplied through the supply hole 3411a of the first filter region 341S. The third gas (G3) is supplied through the supply hole 3412a of the first filter region 341S and through the third supply hole 3512b of the second shower region 351E. The second gas (G2) supplied through the first filter region 341S is provided to the processing space 101 through the through hole 3513. In this case, the third gas (G3) is relatively greater than the second gas (G2) on the edge region of the substrate (W). Accordingly, the etch rate in the edge region of the substrate (W) decreases and the uniformity increases.

Meanwhile, although not described in a separate drawing, the second gas (G2) may be supplied from the first filter region 341S and the second shower region 351E, and the third gas (G3) may be supplied through the first filter region 341S.

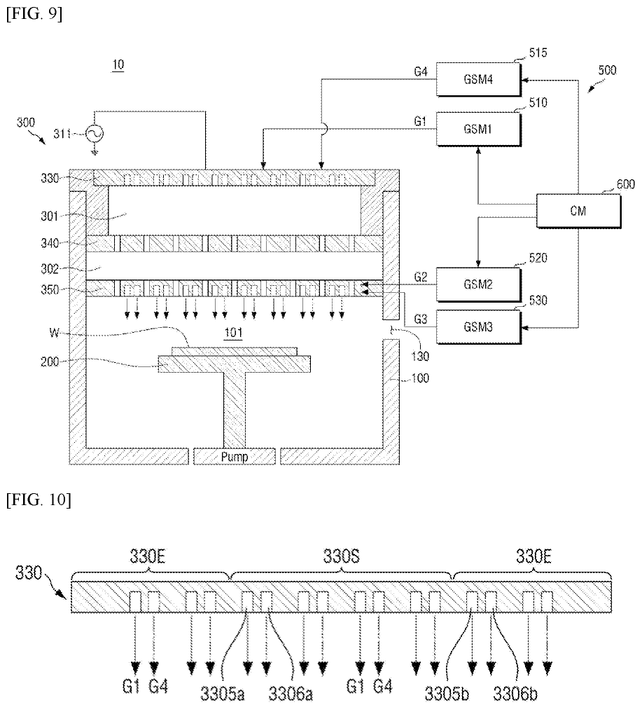

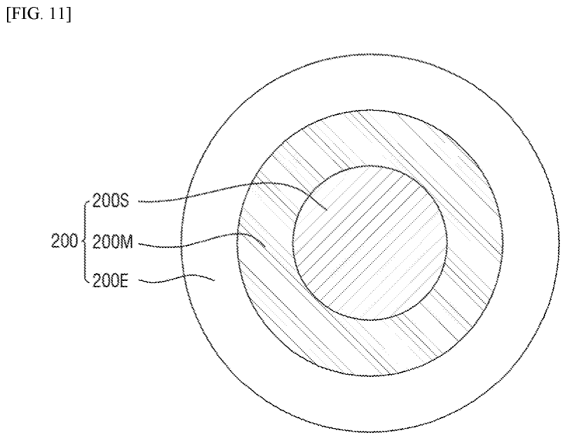

FIG. 9 is a view for describing a substrate processing apparatus according to a sixth embodiment of the present invention. FIG. 10 is a view for describing the electrode of FIG. 9. Hereinafter, differences from those described with reference to FIGS. 1 to 8 will be mainly described.

First, referring to FIG. 9, in the substrate processing apparatus according to the sixth embodiment of the present invention, the gas supply module 500 includes a first gas supply module 510, a second gas supply module 520, a third gas supply as well as a fourth gas supply module 515.

The first gas supply module 510 and the fourth gas supply module 515 respectively supply the first gas (G1) and the fourth gas (G4) to the first space 301 through the electrode 330. The fourth gas (G4) may be a hydrogen-containing gas (e.g., hydrogen gas).

The hydrogen-containing gas (e.g., hydrogen gas) serves to adjust the etch rate. When the flow rate of the hydrogen gas is increased, the etch rate increases and the uniformity decreases. Conversely, when the flow rate of the hydrogen gas is decreased, the etch rate decreases and the uniformity increases. By controlling the flow rate of the hydrogen gas independently from the flow rate of the nitrogen trifluoride gas (i.e., the first gas (G1)), the etch rate can be precisely controlled.

Hereinafter, the case where the first gas (G1) is nitrogen trifluoride (NF₃) gas and the fourth gas (G4) is hydrogen gas will be described in detail.

The first gas (G1) and the fourth gas (G4) are excited in the form of plasma in the first space 301.

NF₃+H₂⬆NH₄F*.HF* (Chemical Formula 4)

The plasma effluent NH₄F*.HF* is provided to the processing space 101 through the ion blocker 340 and the shower head 350. In the processing space 101, NH₄F*.HF* reacts with the second gas (G2) (i.e., NH₃) to generate an etchant.

NH₃+NH₄F*.HF*→NH₄F*⬇+HF* ⬆ (Chemical Formula 5)

In the etchant, NH₄F* decreases, while the amount of HF* increases. As a result, when the fourth gas (G4) is provided to the first space 301, since the amount of HF* increases, the etch rate of silicon oxide can be increased.

On the other hand, as described above, when the third gas (G3) (nitrogen gas) is provided to the processing space 101, the etch rate of silicon oxide may be decreased and uniformity may be increased. This is because the amount of NH₄F* increases while HF* decreases in etchant.

N₂⬆+NH₄F*.HF*→NH₄F* ⬆+HF*⬇ (Chemical Formula 6)

Here, referring to FIG. 10, the electrode 330 includes a first electrode region 330S and a second electrode region 330E disposed outside the first electrode region 330S. The first electrode region 330S may be disposed in the central region of the electrode 330, and the second electrode region 330E may be disposed in the edge region of the electrode 330.

The first gas (G1) and the fourth gas (G4) may be supplied through the first electrode region 330S and the second electrode region 330E. The first gas (G1) is supplied through the supply hole 3305a of the first electrode region 330S and through the supply hole 3305b of the second electrode region 330E. The fourth gas (G4) is supplied through the supply hole 3306a of the first electrode region 330S and through the supply hole 3306b of the second electrode region 330E.

The flow rate of the fourth gas (G4) supplied through the first electrode region 330S and the flow rate of the fourth gas (G4) supplied through the second electrode region 330E may be controlled differently.

When the flow rate of the fourth gas (G4) supplied through the first electrode region 330S is greater than the flow rate of the fourth gas (G4) supplied through the second electrode region 330E, the etchant is increased on the central region of the substrate (W) corresponding to the first electrode region 330S. Accordingly, the etch rate in the central region of the substrate (W) is increased.

On the other hand, if the flow rate of the fourth gas (G4) supplied through the second electrode region 330E is greater than the flow rate of the fourth gas (G4) supplied through the first electrode region 330S, the etchant is increased on the edge region of the substrate (W) corresponding to the second electrode region 330E. Accordingly, the etch rate in the edge region of the substrate (W) is increased.

Alternatively, the flow rate of the first gas (G1) supplied through the first electrode region 330S and the flow rate of the first gas (G1) supplied through the second electrode region 330E may be controlled differently.

In addition, although not shown separately, an inert gas (e.g., Ar, Ne) may be additionally provided through the electrode. The inert gas may be provided together with the first gas (G1) or the fourth gas (G4). The inert gas may help the first gas (G1) or the fourth gas (G4) to move.

In summary, the etch rate of the silicon oxide can be controlled by controlling the flow rate of the fourth gas (G4) (hydrogen gas). The uniformity of silicon oxide can be controlled by controlling the flow rate of the third gas (G3) (nitrogen gas).

In addition, shapes of the electrode 330, the ion blocker 340, and the shower head 350 may be changed as shown in FIGS. 2a, 2b, 5 to 8, and 10. Based on this structure, by controlling the supply position/flow rate of the fourth gas (G4) and the supply position/flow rate of the third gas (G3), the etch rate/uniformity can be controlled in a specific position of the substrate (W) (for example, the central region, the edge region).

Meanwhile, FIG. 11 is a conceptual diagram illustrating a support module of the substrate processing apparatus of FIG. 9.

Referring to FIG. 11, the support module 200 is divided into a plurality of regions 200S, 200M, and 200E, and temperatures of the plurality of regions 200S, 200M, and 200E may be individually controlled. If there is a region in the substrate (W), in which the etch rate needs to be increased (for example, a central region of the substrate (W)), the temperature of the corresponding region (for example, 200S) can be increased.

For example, if the flow rate of the fourth gas (G4) supplied through the first electrode region (330S in FIG. 10) is greater than the flow rate of the fourth gas (G4) supplied through the second electrode region (330E in FIG. 10), the etchant is increased on the central region of the substrate (W) corresponding to the first electrode region 330S. If the temperature of the region 200S is higher than that of the other regions 200M and 200E, the etch rate of the central region of the substrate (W) can be further increased.

Although the embodiments of the present invention have been described with reference to the above and the accompanying drawings, those of ordinary skill in the art to which the present invention pertains can understand that it can be implemented in other specific forms without changing the technical spirit or essential features of the present invention. Therefore, it should be understood that the embodiments described above are illustrative and non-limiting in all respects.

What is claimed is:

1. An apparatus for processing a substrate comprising:
a first space disposed between an electrode and an ion blocker;
a second space disposed between the ion blocker and a shower head;
a processing space for processing a substrate under the shower head;
a first gas supply module for providing a first gas for generating plasma in the first space;
a second gas supply module for providing a second gas to be mixed with an effluent of the plasma in the processing space; and
a third gas supply module for providing a third gas to be mixed with an effluent of the plasma in the processing space,
wherein the first gas is a fluorine-containing gas, the second gas is a nitrogen and hydrogen-containing gas, the third gas is a nitrogen-containing gas different from the second gas, and the substrate includes an exposed silicon and hydrogen-containing region.

2. The apparatus of claim 1, wherein a flow rate control of the second gas and a flow rate control of the third gas are performed independently.

3. The apparatus of claim 2, wherein a uniformity when the third gas is provided at a first flow rate is higher than a uniformity when the third gas is provided at a second flow rate smaller than the first flow rate.

4. The apparatus of claim 1, wherein the ion blocker includes a first filter region and a second filter region disposed outside the first filter region, and the shower head includes a first shower region and a second shower region disposed outside the first shower region.

5. The apparatus of claim 4, wherein the second gas and the third gas are supplied through the first filter region of the ion blocker, and are not supplied through the second filter region,
wherein the second gas and the third gas are not suppled through the first shower region of the shower head, and are supplied through the second shower region.

6. The apparatus of claim 4, wherein the second gas and the third gas are supplied through the first shower region and the second shower region of the shower head,
wherein a flow rate of the third gas supplied through the first shower region is different from a flow rate of the third gas supplied through the second shower region.

7. The apparatus of claim 4, wherein the second gas and the third gas are supplied through the first filter region and the second filter region of the ion blocker,
wherein a flow rate of the third gas supplied through the first filter region is different from a flow rate of the third gas supplied through the second filter region.

8. The apparatus of claim 1, wherein the first gas and the fourth gas are provided through the electrode, and the fourth gas is a hydrogen-containing gas,
wherein a flow rate control of the first gas and a flow rate control of the fourth gas are performed independently.

9. The apparatus of claim 8, wherein the electrode includes a first electrode region and a second electrode region disposed outside the first electrode region,
wherein the first gas and the fourth gas are supplied through the first electrode region and the second electrode region, and a flow rate of the fourth gas supplied through the first electrode region and a flow rate of the fourth gas supplied through the second electrode region are different from each other.

10. The apparatus of claim 9, wherein a flow rate of the fourth gas supplied through the first electrode region is greater than a flow rate of the fourth gas supplied through the second electrode region,
wherein a support module for supporting the substrate is disposed in the processing space, and the support module is divided into a plurality of regions, and a temperature of a centrally located region among the plurality of regions is increased higher than a temperature of other regions.

11. The apparatus of claim 8, wherein an inert gas is additionally provided through the electrode.

12. An apparatus for processing a substrate comprising:
a first space disposed between an electrode connected to a high frequency power supply and an ion blocker connected to a constant voltage;
a second space disposed between the ion blocker and a shower head;
a processing space for processing a substrate under the shower head;
a first gas supply module for providing nitrogen trifluoride gas for generating plasma through the electrode in the first space;
a second gas supply module for providing hydrogen gas for generating plasma through the electrode in the first space; and
a third gas supply module for providing a first ammonia gas through a central region of the ion blocker, and providing a second ammonia gas through an edge region of the shower head to mix the first ammonia gas, the second ammonia gas, and an effluent of the plasma.

13. The apparatus of claim 12, wherein a flow rate of the first ammonia gas and a flow rate of the second ammonia gas are different from each other.

14. The apparatus of claim 12 further comprises,
a fourth gas supply module for providing a first nitrogen gas through a central region of the ion blocker to mix the first nitrogen gas and an effluent of the plasma, and providing a second nitrogen gas through an edge region of the shower head to mix the second nitrogen gas and an effluent of the plasma.

15. The apparatus of claim 14, wherein a flow rate of the first nitrogen gas and a flow rate of the second nitrogen gas are different from each other.

16. The apparatus of claim 12, wherein the electrode includes a first electrode region located at a center and a second electrode region disposed outside the first electrode region,
wherein the nitrogen trifluoride gas and the hydrogen gas are supplied through a first electrode region and a second electrode region, a flow rate of the hydrogen gas supplied through the first electrode region and a flow rate of the hydrogen gas supplied through the second electrode region are different from each other.

17. The apparatus of claim 16, wherein a flow rate of the nitrogen trifluoride gas supplied through the first electrode region and a flow rate of the nitrogen trifluoride gas supplied through the second electrode region are different from each other.

18. A method for processing a substrate comprising:
providing a substrate processing apparatus including a first space disposed between an electrode and an ion blocker, a second space disposed between the ion blocker and a shower head, and a processing space for processing a substrate under the shower head;
locating a substrate including an exposed silicon and hydrogen-containing region in the processing space;
providing, in a first section, a nitrogen-containing gas and a nitrogen and hydrogen-containing gas in the processing space to form an atmosphere in a chamber; and
providing, in a second section, a fluorine-containing gas and a hydrogen-containing gas in the first space while providing a nitrogen-containing gas and a nitrogen and hydrogen-containing gas in the processing space to form a plasma in the first space, and mixing a radical filtered by the ion blocker in an effluent of the plasma, the nitrogen-containing gas, and the nitrogen and hydrogen-containing gas.

19. The method of claim 18 further comprises,
controlling an etching uniformity of the substrate by controlling a flow rate of the nitrogen-containing gas.

20. The method of claim 19, wherein the ion blocker includes a first filter region and a second filter region disposed outside the first filter region,
wherein the shower head includes a first shower region and a second shower region disposed outside the first shower region,
wherein the nitrogen-containing gas and the nitrogen and hydrogen-containing gas are supplied through the first filter region of the ion blocker, and are not supplied through the second filter region,
wherein the nitrogen-containing gas and the nitrogen and hydrogen-containing gas are not supplied through the first shower region of the shower head, and are supplied through the second shower region.
